(19) United States
(12) Patent Application Publication
(10) Pub. No.: US 2024/0297530 A1
(43) Pub. Date: Sep. 5, 2024

(54) PRODUCTION METHOD TO ACCOMPLISH SYNCHRONOUS RESONANCE OF ELECTRICAL MOLECULES

(71) Applicant: Yu-te WANG, Kaohsiung City (TW)

(72) Inventor: Yu-te WANG, Kaohsiung City (TW)

(21) Appl. No.: 18/117,254

(22) Filed: Mar. 3, 2023

(51) Int. Cl. H02J 50/00

(52) U.S. Cl. CPC H02J 50/00; H03L 7/26

(57) ABSTRACT

The production method to accomplish synchronous resonance of electrical molecules includes: restructuring mineral elements to form an activated mineral element featuring molecular synchronous resonance; building a molecular synchronous resonance device using the activated mineral element as a technical feature; and transferring the molecular resonance wave frequency of 10¹⁴ times per minute into an electronic device or component in the form of waves through said molecular synchronous resonance device.

### FIELD OF THE INVENTION

The present invention relates generally to a production method to accomplish synchronous resonance of electrical molecules, and more particularly to a method for building a molecular synchronous resonance device using an activated mineral element with its element wavelength ranging from 1100 nm to 2500 nm and its wave frequency ranging from 1.2×1014 to 2.7×1014. Through the molecular synchronous resonance device, the molecular synchronous resonance frequency of 10¹⁴ times per minute is transferred to an electronic device or component in the form of waves. When electricity passes through the transferred electronic device or component, the molecular motion of the electrical molecules during the power transmission will have a synchronous resonance frequency of 10¹⁴ times per minute.

### DESCRIPTION OF RELATED ART

Referring to FIG. 1 for the normal process of electrical power transmission. As shown in the figure, when electrical power is transmitted through the transmission structure 1 (using a cable as an example herein), because the frequency of the electrical current 2 is unstable during the transmission, there will be interference between the different frequencies of the electrical current. As a result, during the process of power transmission from the electricity generating end to the residential or industrial user ends, the interference will cause energy loss. The electrical energy received by the client end may be only half of the original energy. The other half is lost during the transmission with interference. This early method for electrical power transmission is not ideal.

At present, in order to solve the problem of electrical energy loss caused by interference, the transmission device is provided with an insulator to improve the stability of the frequency of the electrical current, thus improving the efficiency of electrical power transmission.

However, although the addition of the insulator can reduce interference, it is still limited in preventing interference and cannot substantially reduce the loss of electrical power.

Therefore, it has become an important task for experts in this field to find a solution to achieve synchronous resonance of the electrical molecule so that power transmission will not be affected by interference and the loss of electrical energy during transmission will be reduced to save energy. In view of this, the inventor has come up with the present invention after years of effort through in-depth researches in finding a solution to overcome the above problem.

### SUMMARY OF THE INVENTION

The inventor has been dedicated to researches in the field of quantum energy for many years, aiming to find a solution to accomplish synchronous resonance with the frequency of the molecular motion of the electrical molecules reaching 10¹⁴ times per minute, so that electrical power transmission will not be affected by the interference, and the loss of electrical power during the process of transmission will be reduced to save energy. Based on years of experience in research and development in the related field, the inventor developed the present invention after relentless effort and numerous attempts in finding effective solutions.

The main object of the present invention is to provide a production method to accomplish synchronous resonance of electrical molecules. Through a resonance medium with its element wavelength ranging from 1100 nm to 2500 nm and its wave frequency ranging from 1.2×10¹⁴˜2.7×10¹⁴, the resonance frequency of the molecular motion of the electrical molecules can be synchronous to 10¹⁴ times per minute.

The second object of the present invention is to provide a production method to accomplish synchronous resonance of electrical molecules. When the molecular motion of the electrical molecules reaches a resonance frequency of 10¹⁴ times per second, it will be similar to the molecular motion of light, and the transmission mode of electricity will be close to the rectilinear motion mode of light, so that power transmission will not be affected by interference, and the loss of electrical power during the process of transmission will be reduced to save energy.

The third object of the present invention is to provide a production method to accomplish synchronous resonance of electrical molecules. The synchronous resonance of the electrical molecules can help save electrical power, so that it can be applied in various fields for power transmission and power switching.

Based on the above objects, the production method to accomplish synchronous resonance of electrical molecules disclosed in the present invention is mainly based on a resonance medium with its element wavelength ranging from 1100 nm to 2500 nm, and its wave frequency ranging from 1.2×10¹⁴ to 2.7×10¹⁴. This resonance medium is configured on the object or structural substance for electrical power transmission, so that the molecular motion of the electrical molecules will have a synchronous resonance frequency of 1014 times per minute. The synchronous resonance frequency of 1014 times per minute is similar to the molecular motion frequency of light, and the transmission mode of electricity will be close to the rectilinear motion mode of light, so that power transmission will not be affected by interference, and the loss of electrical power during the process of transmission will be reduced to save energy. Moreover, based on the method to accomplish synchronous resonance of the molecular motion of the electrical molecules, the electrical molecule resonance method can be applied in various fields for power transmission and power switching.

### BRIEF DESCRIPTION OF THE DRAWINGS

FIG. 1 is a schematic view of the conventional power transmission.

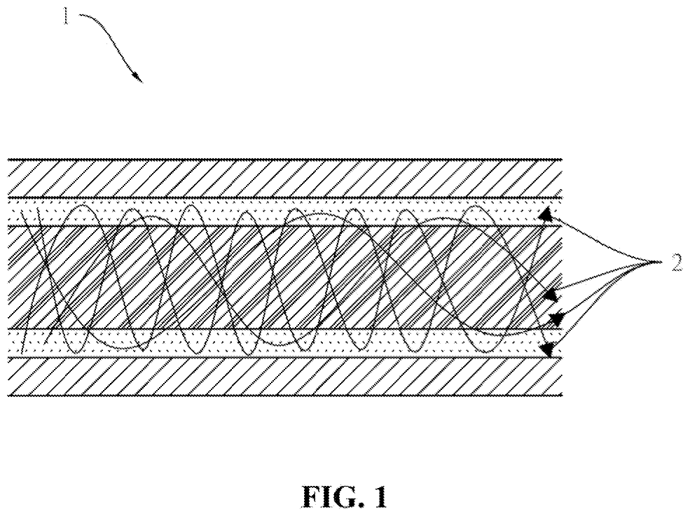

FIG. 2 is a schematic view of the flow structure of the present invention.

FIG. 3 is a schematic view of the steps of the present invention to accomplish synchronous resonance of electrical molecules.

FIG. 4 is a sectional view of the cable structure after synchronous resonance of electrical molecules according to the present invention.

FIG. 5 is a schematic view of the application of the production method to accomplish synchronous resonance of electrical molecules in an electrical power transmission device.

### DETAILED DESCRIPTION OF THE INVENTION

For better understanding of the objects, functions, and structural features of the present invention, a preferred embodiment is used below for detailed description of the invention with reference to the accompanying drawings.

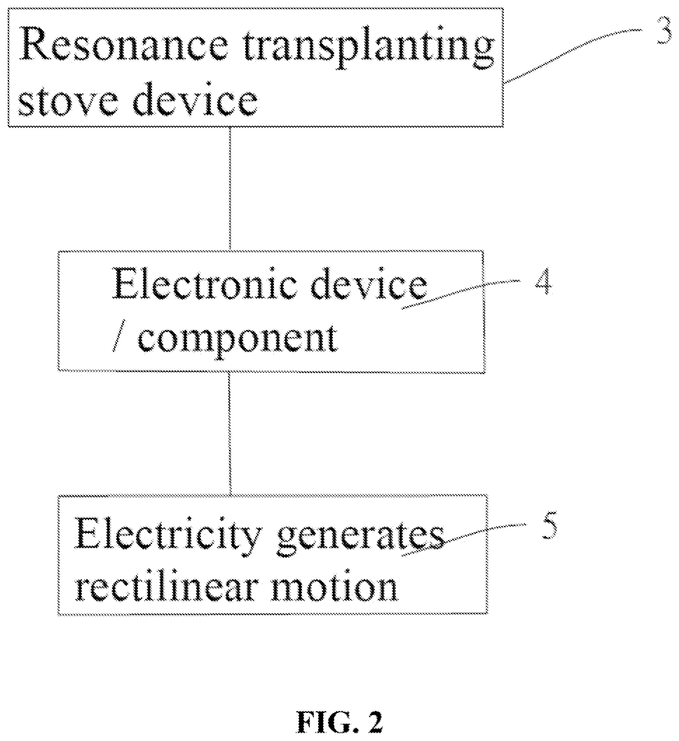

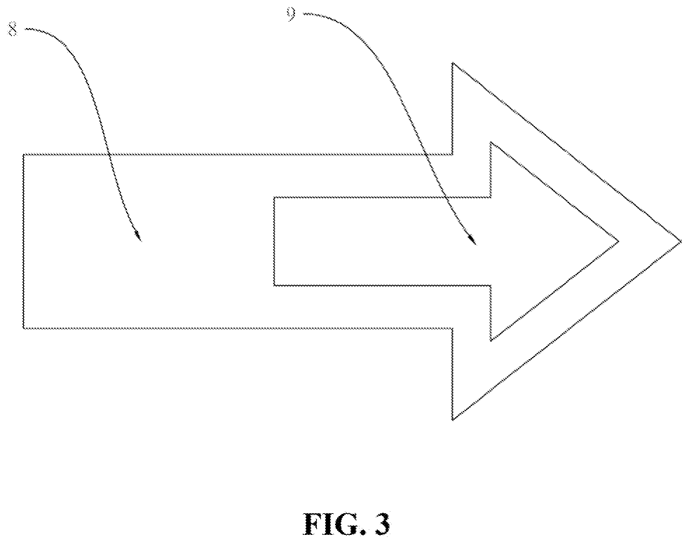

Referring to FIG. 2 and FIG. 3, the present invention mainly provides a production method to accomplish synchronous resonance of electrical molecules, which includes the following steps. In FIG. 3, the reference numeral (8) represents “a resonance medium with its element wavelength ranging from 1100 nm to 2500 nm and its wave frequency ranging from 1.2×1014 to 2.7×1014.” The resonance medium is configured in the process of electrical power transmission. In FIG. 3, the reference numeral (9) represents “the transmission process of electricity.”

Firstly, a plurality of mineral elements are restructured to form a activated mineral element having the feature of molecular synchronous resonance, so that the wavelength of the activated mineral element ranges from 1100 nm to 2500 nm, i.e., its wave frequency ranges from 1.2×10¹⁴ to 2.7×10¹⁴.

Then, the activated mineral element is used to build a molecular synchronous resonance device 3. Said molecular synchronous resonance device 3 has a technical feature that the molecular resonance wave frequency can reach 10¹⁴ times per minute, and the wave frequency ranges from 1.2×10¹⁴ to 2.7×10¹⁴.

Through said molecular synchronous resonance device 3, the molecular resonance wave frequency up to 10¹⁴ times per minute is transferred in the form of waves into an electronic device or component 4, which is configured in the transmission of electrical power. As the resonance wave frequency of the resonance medium is 1.2×10¹⁴˜2.7×10¹⁴, during the process of power transmission, the molecular motion of the electrical molecules can be synchronous to a resonance frequency of 10¹⁴ times per minute. The synchronous resonance frequency of 10¹⁴ is similar to the molecular motion frequency of light. The transmission rate of light is 300,000 kilometers per second. When the molecular motion of the electrical molecules reaches a synchronous resonance frequency of 10¹⁴ times per minute, the transmission mode of electricity will be close to the rectilinear motion mode of light, i.e., the electricity generates a rectilinear motion 5, so as to avoid the negative effect of interference in the process of conventional electrical power transmission. Said method can help reduce the loss of electrical power during the process of power transmission due to interference. Therefore, it is indeed an energy-saving invention.

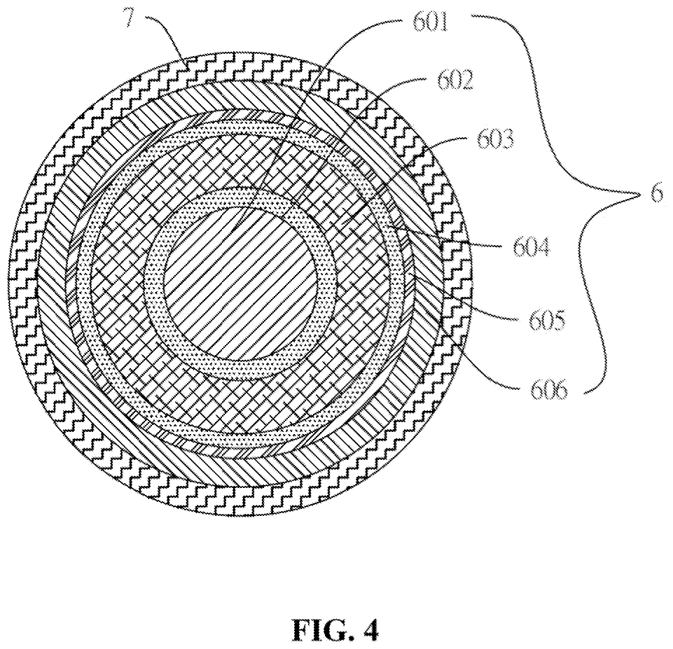

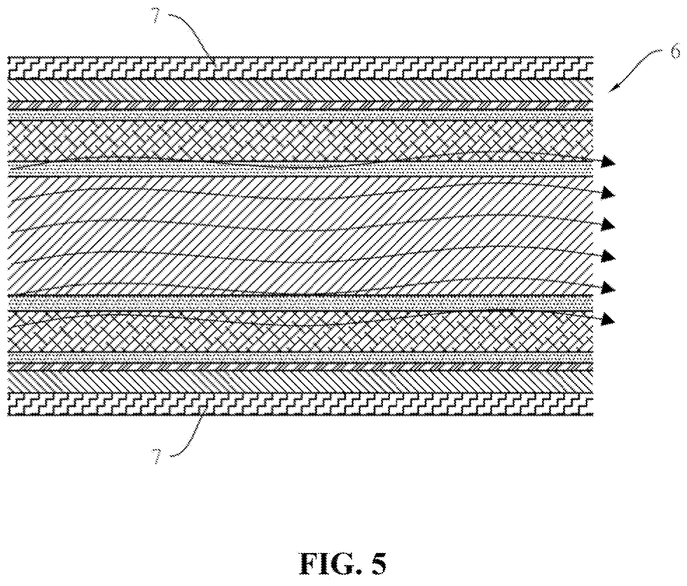

Referring to FIG. 4, in the center of the cable 6, copper conductor 601 is configured as the main material for conduction of electricity. Then, outside the copper conductor 601, an internal conducting layer 602, an insulator 603, an external conducting layer 604, and a masking layer 605 are configured sequentially. In the end, a PVC material 606 is configured to enclose the cable 6. For the application of the present invention, the outer layer of the cable 6 can be configured with a resonance structure 7. As the element wavelength of the resonance structure 7 ranges from 1100 nm to 2500 nm, and its wave frequency ranges from 1.2×10¹⁴ to 2.7×10¹⁴, the cable 3 has synchronous resonance. During the transmission of electrical power in the cable 6, as the molecular motion of the electrical molecules with a wave frequency up to 10¹⁴ times per minute is similar to the molecular motion of light, the transmission mode of electricity is close to the rectilinear motion of light (see FIG. 5). Thus, the cable 6 can transmit electrical power more stably, solving the problem of power loss due to unstable electrical current.

From the above descriptions, it is clear that the method to accomplish synchronous resonance of electrical molecules can be applied in various fields for power transmission and power switching, such as residential electricity, industrial electricity and switches of electric appliances. Based on the principle to accomplish synchronous resonance of the molecular motion of the electrical molecules, the transmission of electrical power tends to be stable. Therefore, the resonance method for synchronizing molecular motion of the electrical molecules can be applied in various fields for power transmission and power switching.

To summarize, the present invention production method to accomplish synchronous resonance of electrical molecules has been developed by the inventor after years of deliberation. It features practical functions as well as simplified usage, and truly meets the prerequisites for a patent as specified in the Patent Law. Therefore, an application for patent is hereby submitted. Your examination and approval will be highly appreciated.

Although the invention has been explained in relation to its preferred embodiment, it is to be understood that many other possible modifications and variations can be made without departing from the spirit and scope of the invention as hereinafter claimed.

### NOTATIONS

1 . . . transmission structure
2 . . . unstable electrical current
3 . . . molecular synchronous resonance device
4 . . . electronic device or component
5 . . . electricity generates rectilinear motion
6 . . . cable
601 . . . copper conductor
602 . . . internal conducting layer
603 . . . insulators
604 . . . external conducting layer
605 . . . masking layer
606. . . . PVC material
7 . . . resonance structure

What is claimed is:

1. A production method to accomplish synchronous resonance of electrical molecules, including:
restructuring mineral elements to form an activated mineral element featuring molecular synchronous resonance, with the wavelength of the activated mineral element ranging from 1100 nm to 2500 nm, i.e., its wave frequency ranging from 1.2×10¹⁴ to 2.7×10¹⁴;
building a molecular synchronous resonance device using the activated mineral element as a technical feature, wherein the resonance wave frequency of the molecular synchronous resonance device can reach 10¹⁴ times per minute, with the wave frequency ranging from 1.2×10¹⁴ to 2.7×10¹⁴; and
transferring the molecular resonance wave frequency of 10¹⁴ times per minute into an electronic device or component in the form of waves through said molecular synchronous resonance device configured in the transmission of electrical power, as the resonance wave frequency of the resonance medium is 1.2×10¹⁴˜2.7×10¹⁴.
wherein, during the process of power transmission, the molecular motion of the electrical molecules can be synchronous to a resonance frequency up to 10¹⁴ times per minute, the synchronous resonance frequency of 10¹⁴ times per minute is similar to the molecular motion frequency of light, and the transmission mode of electricity is close to the rectilinear motion mode of light, thus avoiding the negative effect of interference in the process of conventional electrical power transmission, and therefore, the present invention can help to reduce the loss of electrical power during the process of power transmission due to interference, and can consequently contribute to energy-saving,
wherein, through the above steps, the method to accomplish synchronous resonance of the molecular motion of the electrical molecules can be applied in various fields for power transmission and power switching, such as: residential electricity, industrial electricity, and switches for electric appliances, based on the principle to accomplish synchronous resonance of the molecular motion of the electrical molecules,
wherein the transmission mode of electricity will be close to the rectilinear motion mode of light, and therefore, the resonance method for synchronizing molecular motion of the electrical molecules can be applied in various fields for power transmission and power switching.
